(19) United States
(12) Patent Application Publication
(10) Pub. No.: US 2007/0013025 A1
(43) Pub. Date: Jan. 18, 2007

(54) SEMICONDUCTOR MEMORY DEVICE AND METHOD OF MANUFACTURING THE SAME

(76) Inventor: Chear-Yeon MUN, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/457,122

(22) Filed: Jul. 12, 2006

(30) Foreign Application Priority Data
Jul. 18, 2005 (KR) 10-2005-64965

(51) Int. Cl. H01L 29/00

(52) U.S. Cl. 257/529

(57) ABSTRACT

A semiconductor memory device includes an insulation layer disposed in a fuse region of a substrate, a fuse including a conductive pattern disposed on the insulation layer and a metal pattern disposed in physical contact with the conductive pattern, the conductive pattern composed of a material that thermally explodes when it absorbs a laser beam.

### CROSS REFERENCE TO RELATED APPLICATIONS

This application claims priority from Korean Patent Application No. 10-2005-64965 filed on 18 Jul. 2005 in the Korean Intellectual Property Office. Korean Patent Application No. 10-2005-64965 is incorporated by reference in its entirety.

### BACKGROUND

1. Field of the Invention

This disclosure relates generally to semiconductor memory devices and methods of fabricating the same and more particularly, to a semiconductor device and method of fabricating same that is capable of preventing generation of residue during a repairing process.

2. Description of the Related Art

In general, a semiconductor memory device is generally manufactured in a wafer fabrication process where circuit patterns are repeatedly formed on a wafer to form cells having integrated circuits, and a package assembly process in which the wafer having the cells are assembled in a suitable form.

After the wafer fabrication process but before the package assembly process, an electric die sorting (EDS) test may be performed to determine the electrical characteristics of each cell formed on the wafer, i.e., whether the chip is acceptable or faulty.

The test process monitors the performance of the semiconductor devices so that failed cells are sorted. After the test process, the sorted failed cells may be replaced with redundant cells using a repairing process. Thus, in actual operation, the chips operate normally, thereby improving the yield of semiconductor memory devices.

The repairing process is performed by irradiating a laser beam into a wiring that is connected to a failed cell and cutting the wiring. The wiring cut by the laser beam is referred to as a fuse and a region surrounding the cut wiring is referred to as a fuse region.

As semiconductor devices become more highly integrated, a metal fuse or a conductive layer as an upper metal wiring of the semiconductor device has conventionally been used. The conventional fuse using the metal wiring has a stacked structure including a barrier metal layer and a metal layer. During a repairing process, it sometimes happens that the barrier metal layer is not completely cut off by a laser beam. As a result, residues are often left after the repairing process, resulting in a leakage current.

Embodiments of the invention address these and other disadvantages of the conventional art.

### SUMMARY

According to some embodiments of the invention, a semiconductor memory device is capable of preventing residues from being generated during a repairing process. According to some other embodiments of the invention, a method of fabricating a semiconductor memory device is capable of preventing residues from being generated during a repairing process.

### BRIEF DESCRIPTION OF THE DRAWINGS

The above and other features and advantages of the invention will become more apparent by describing in detail exemplary embodiments thereof with reference to the attached drawings.

FIG. 1 is a sectional diagram illustrating a semiconductor memory device according to some embodiments of the invention.

FIGS. 2 through 6 are sectional diagrams illustrating exemplary processes in a method for fabricating the semiconductor memory device of FIG. 1.

FIG. 7 is a sectional diagram illustrating a semiconductor memory device according to some other embodiments of the invention.

FIGS. 8 through 13 are sectional diagrams illustrating exemplary processes in a method for fabricating the semiconductor memory device of FIG. 7.

### DETAILED DESCRIPTION

Advantages and features of the invention and may be understood more readily by reference to the following detailed description of preferred embodiments and the accompanying drawings. The invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

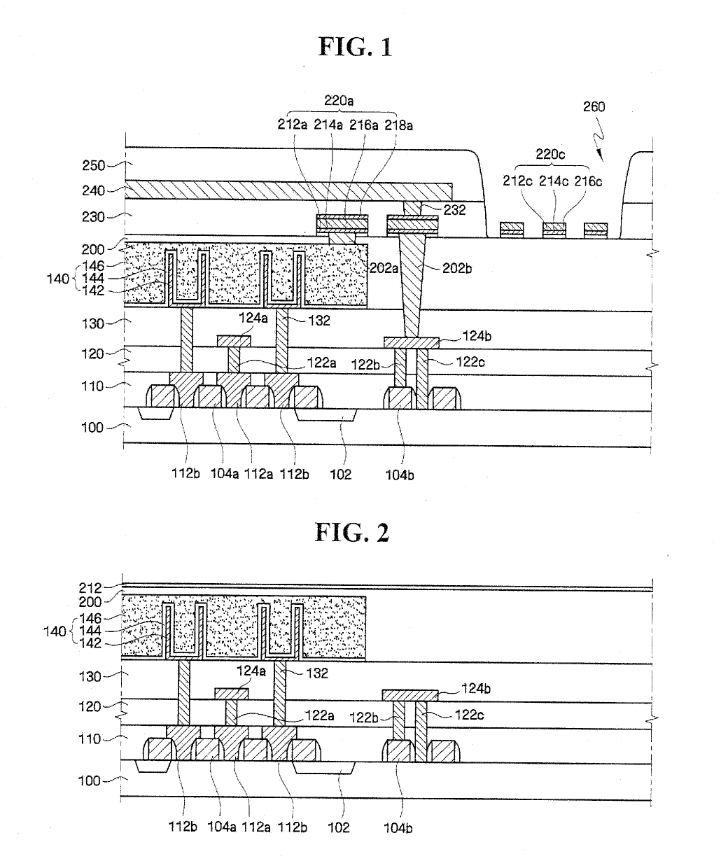

FIG. 1 is a sectional diagram illustrating a semiconductor memory device according to some embodiments of the invention.

Referring to FIG. 1, a semiconductor substrate 100 is divided into a cell array region and a peripheral circuit region. Device isolation layer patterns 102 are formed on the substrate to divide the substrate 100 into active regions and field regions. Gate electrodes 104a and 104b are formed on the substrate 100 in the cell array region and the peripheral circuit region, respectively. Impurity doped regions (not shown) are formed in the substrate 100 on both sides of the gate electrodes 104a and 104b.

A first interlayer insulating layer 110 is formed on the gate electrodes 104a and 104b. The first interlayer insulating layer in the cell array region includes a bit line contact pad 112a therein for electrically connecting an impurity doped region (not shown) and a bit line 124a and also includes a lower electrode contact pad 112b therein for electrically connecting an impurity doped region (not shown) and a lower electrode 142 of a capacitor 140.

A second interlayer insulating layer 120 is formed on the first interlayer insulating layer 110 in the cell array region, and the second interlayer insulating layer 120 has a bit line contact 122a for electrically connecting the bit line 124a and the bit line contact pad 112a. The first interlayer insulating layer 110 and the second interlayer insulating layer 120 formed in the peripheral circuit region include contacts 122b and 122c therein for connecting to the gate electrode 104b and an impurity doped region (not shown), respectively.

A third interlayer insulating layer 130 is disposed on the second interlayer insulating layer 120, the third interlayer insulating layer 130 having the bit line 124a connected to the bit line contact 122a, and a wiring 124b connected to the contacts 122b and 122c disposed in the peripheral region. The second and third interlayer insulating layers 120 and 130 in the cell array region include lower electrode contacts 132 therein for electrically connecting the lower electrode contact pads 112b and the lower electrodes 142.

A cylinder-type capacitor 140 including a lower electrode 142 electrically connected to the lower electrode contact 132, a dielectric layer 144 conformably formed on the surface of the lower electrode 142, and an upper electrode 146 are disposed on the third interlayer insulating layer 130. Another type of the capacitor 140 may be formed, for example, a stack type. In addition, a fourth interlayer insulating layer 200 is disposed on the cylinder-type capacitor 140.

On the fourth interlayer insulating layer 200, first wirings 220a are formed in the cell array region and the peripheral region and a fuse 220c is formed in the fuse region. The fuse 220c is formed by stacking a metal pattern 216c on a conductive pattern 212c. The conductive pattern 212c is formed of a material that absorbs laser beam energy during a repairing process and is subjected to thermal explosion. The fuse 220c has a barrier metal pattern 214c formed between the conductive pattern 212c and the metal pattern 216c, for preventing oxidation of the metal pattern 216c.

When the temperature of the conductive pattern 212c rises to a predetermined degree, the conductive pattern 212c is turned into a gas state and a thermal explosion occurs. That is, the metal patterns 214c and 216c formed over the conductive pattern 212c are blown off. Thus, a metal pattern residue does not remain after the repairing process since the metal patterns 214c and the 216c are converted into a gas state via a liquid state, thereby blowing the metal patterns 214c and 217c, which is called thermal explosion.

The conductive pattern 212c may be formed of polysilicon and the metal pattern 216c may be formed of titanium (Ti), aluminum (Al), tungsten (W), copper (Cu), and the like. The barrier metal pattern 214c may be formed of a refractory metal, a refractory metal compound, and/or a composite layer of a refractory metal and a refractory metal compound such as titanium (Ti), tantalum (Ta), titanium nitride (TiN), or tantalum nitride (TaN).

The first wiring 220a on the fourth interlayer insulating layer 200 in the cell array region and the peripheral circuit region and the fuse 220c in the fuse region are formed on the same layer and have the same structure. That is, the first wiring 220a has a structure including a conductive pattern 212a, a barrier metal pattern 214a and a metal pattern 216a, which are stacked in this order, and the fuse has a structure including a conductive pattern 212c, a barrier metal pattern 214c, and a metal pattern 216c stacked in this order. The first wiring 220a further includes a capping layer pattern 218a which prevents damage of the metal pattern 216a. Contacts 202a and 202b are disposed in the conductive pattern 212a and the fourth interlayer insulating layer 200, respectively, the contacts 202a and 202b electrically connecting the conductive pattern 212a disposed under the barrier metal pattern 214a of the first wiring 220a with the upper electrode 146 of the capacitor 140 or the wiring 124b in the cell array region.

A fifth interlayer insulating layer 230 is disposed over the first wiring 220a, and a second wiring 240 electrically connected to the first wiring 220a is disposed on the fifth interlayer insulating layer 230 in the cell array region. A protective layer 250 is formed on the second wiring 240. An opening 260 exposing the fuse 220c is formed in the fifth interlayer insulating layer 230 and the fuse region of the protective layer 250.

Hereinafter, a method for fabricating the semiconductor memory device of FIG. 1 will be described with reference to FIGS. 2 through 6. FIGS. 2 through 6 are sectional diagrams illustrating exemplary processes of a method for fabricating the semiconductor memory device shown in FIG. 1.

Referring to FIG. 2, a device isolation process is performed to form device isolation layer patterns 102 on a substrate 100 to isolate each memory cell from other adjacent cells. Then, gate electrodes 104a and 104b are formed on the substrate 100 having the device isolation layer patterns 102. Accordingly, the substrate 100 is defined by an active area and a field area. A local oxidation (LOCOS) process or a shallow trench isolation (STI) process may be employed for device isolation.

The gate electrodes 104a and 104b may be formed by any well known method. The gate electrodes 104a and 104b are disposed in the cell array region and the peripheral circuit region.

Using the gate electrodes 104a and 104b as an ion implantation mask, boron (B) or phosphorous (P) ions are implanted in the substrate 100 to form impurity doped regions (not shown). Next, a silicon nitride layer is deposited on the surface of the substrate 100 having the gate electrodes 104a and 104b thereon, and then anisotropically etched to form gate spacers on sidewalls of the gate electrodes 104a and 104b.

Next, an insulation layer of an oxide material is deposited on the surface of the resultant structure and planarized by a chemical mechanical polishing (CMP) process to form the first interlayer insulating layer 110. Photoresist patterns (not shown) for forming a bit line contact pad 112a and a lower electrode contact pad 112b are formed on the first interlayer insulating layer 110, and the first interlayer insulating layer 110 is partially etched to expose the impurity doped region (not shown) in a cell array region. Here, examples of the conductive materials for forming the bit line contact pad 112a and the lower electrode contact pad 112b include doped polysilicon or tungsten.

Then, a conductive material is deposited on a surface of the resultant structure by a chemical vapor deposition (CVD) process and is planarized by a CMP process or an etch back process until the first interlayer insulating layer 110 is exposed, to form the bit line contact pad 112a and the lower electrode contact pad 112b. The bit line contact pad 112a and the lower electrode contact pad 112b are electrically connected to the respective impurity doped regions (not shown). Next, the second interlayer insulating layer 120 is formed on the resultant structure, and photoresist patterns (not shown) for forming a bit line contact 122a and a wiring contact 122b, which will be formed in the peripheral circuit region in a subsequent process, are formed on the second interlayer insulating layer 120. Using the photoresist patterns as an etch mask, the second interlayer insulating layer 120 is partially etched to expose the bit line contact pad 112a, and the second interlayer insulating layer 120 and the first interlayer insulating layer 110 in the peripheral circuit region are sequentially etched to expose the impurity doped regions (not shown) and the gate electrode (104b). Then, a conductive material is deposited on the entire surface of the substrate 100 and planarized to form the bit line contact 122a and the wiring contact 122b in the peripheral circuit region.

Next, a conductive layer is formed on the second interlayer insulating layer 120, and then a photo-etching process is performed with respect to the conductive layer to form the bit line 124a and the wiring 124b in the peripheral circuit region. In this instance, the bit line 124a formed on the second interlayer insulating layer 120 is connected to the bit line contact 122a formed in the second interlayer insulating layer 120, and the wiring 124b in the peripheral circuit region is connected to the wiring contact 122b formed in the peripheral circuit region. Then, the third interlayer insulating layer 130 that is planarized is formed on a surface of the resultant structure.

Photoresist patterns (not shown) to be used as etch masks, are formed on the third interlayer insulating layer 130. Using the photoresist patterns as etch masks, the third interlayer insulating layer 130 and the second interlayer insulating layer 120 are sequentially and partially etched to expose the lower electrode contact pad 112b. Next, a conductive material layer is formed on a surface of the resultant structure of the substrate 100 and planarized to form the lower electrode contact 132 that is electrically connected to the lower electrode contact pad 112b.

Next, the capacitor 140 is formed on the third interlayer insulating layer 130. Here, the capacitor 140 may be any one of a number of various types, including a stack type capacitor, a cylinder type capacitor, and so on. In the illustrated embodiments, a cylinder type capacitor is formed.

In order to form the capacitor 140, a sacrificial layer (not shown) for a mold is formed on the third interlayer insulating layer 130, a conductive layer for the lower electrode is formed on sidewalls and the upper surface of the mold, and then an insulation layer (not shown) with a good gap filling characteristic is deposited. A planarization process is performed to expose the sacrificial layer (not shown) for the mold, and then the insulation layer and the sacrificial layer for the mold are removed to form a cylinder-type lower electrode 142. Then, a dielectric layer 144 and a conductive layer 146 for the upper electrode are deposited sequentially on the surface of the lower electrode 142 and patterned to complete the formation of the capacitor 140.

After forming the capacitor 140 as described above, an insulation layer formed of an oxide material is deposited on the entire surface of the resultant structure. The insulation layer is subjected to a planarization process such as a CMP or an etch back to form the fourth interlayer insulating layer 200. Here, the fourth interlayer insulating layer 200 may be formed of a borosilicate glass (BSG) layer, a phosphosilicate glass (PSG) layer, a borophosphosilicate glass (BPSG) layer, an undoped silicate glass (USG) layer, a tetra-ethyl-ortho-silicate (TEOS) layer, an O₃-TEOS layer, a PE (Plasma Enhanced)-TEOS layer, and the like.

A conductive layer 212 made of a material that causes a thermal explosion when it absorbs sufficient energy from a laser beam is formed on the fourth interlayer insulating layer 200. In this instance, the conductive layer 212 is preferably formed of a polysilicon layer.

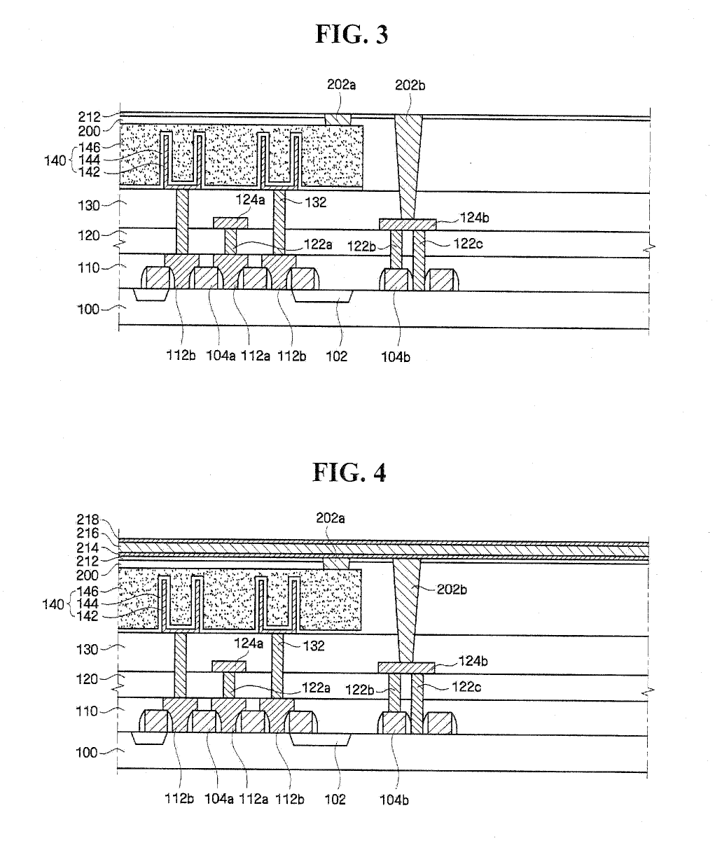

Referring to FIG. 3, the conductive layer 212 and the fourth interlayer insulating layer 200 are partially etched to partially expose the upper electrode 146 of the capacitor 140 and the wiring 124b in the peripheral circuit region. Then, a conductive material is deposited on the entire surface of the resultant structure and is planarized until the conductive layer 212 is exposed to form the wiring contacts 202a and 202b. The wiring contacts 202a and 202b may be formed of doped polysilicon or tungsten.

Referring to FIG. 4, a barrier metal layer 214, a metal layer 216, and a capping layer 218 are sequentially formed on the conductive layer 212 including parts of the wiring contacts 202a and 202b. The barrier metal layer 214 is formed for preventing a metallic material of the overlying metal layer 216 from being diffused or oxidized. The barrier metal layer 214 may be formed of a refractory metal, a refractory metal compound, and/or a composite layer of a refractory metal and a refractory metal compound such as titanium (Ti), tantalum (Ta), titanium nitride (TiN), or tantalum nitride (TaN). The metal layer 216 may be made of aluminum (Al), tungsten (W), copper (Cu), and the like. The capping layer is disposed over the metal layer 216, prevents the metal layer 216 from being damaged, and may be made of the same material as the metal layer 216.

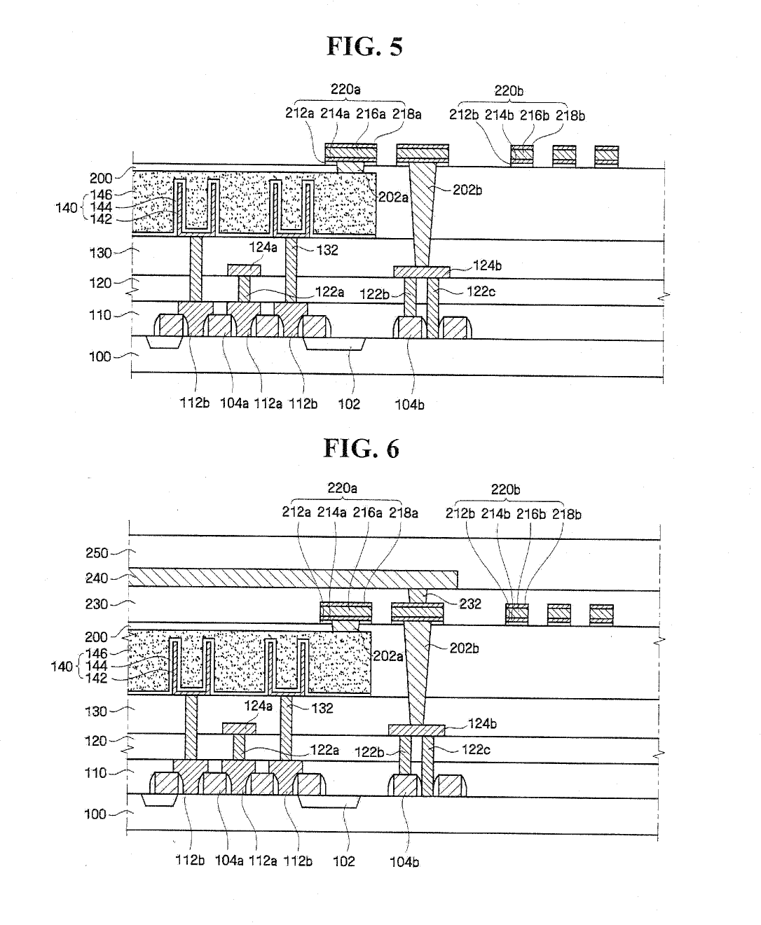

Referring to FIG. 5, photoresist patterns (not shown) for forming a first wiring 220a and a fuse pattern 220b are formed on the capping layer 218, and the capping layer 218, the metal layer 216, the barrier metal layer 214 and the conductive layer 212 are sequentially and partially etched using the photoresist patterns as an etch mask to form the first wiring 220a and the fuse pattern 220b on the fourth interlayer insulating layer 200. In this instance, the first wiring 220a is connected to the wiring contacts 202a and 202b formed in the fourth interlayer insulating layer 200.

Referring to FIG. 6, the fifth interlayer insulating layer 230 is formed to cover the first wiring 220a and the fuse pattern 220b formed on the fourth interlayer insulating layer 200. The fifth interlayer insulating layer 230 has a contact 232 for connecting wirings therein. Next, a metal layer for a second wiring is deposited on the fifth interlayer insulating layer 230 having the contact 232 therein and patterned to form the second wiring 240 disposed in the cell array region and the peripheral circuit region. In this instance, a barrier metal layer (214 of FIG. 4) can be formed under the second wiring 240 and a capping layer (218 of FIG. 4) can be formed on the second wiring 240. Next, the protective layer 250 is deposited to cover the resultant structure of the substrate 100.

Next, photoresist patterns (not shown), which are used as etch masks to expose the fuse pattern 220b, are formed on the protective layer 250, and the protective layer 250 and the fifth interlayer insulating layer 230 are sequentially and partially etched using the photoresist pattern as an etch mask until the upper surfaces of the fourth interlayer insulating layer 200 and the fuse pattern 220b are exposed, thereby forming openings (260 of FIG. 1). The fuse pattern 220b is partially dry etched. That is, a part of the capping pattern 218b and the metal pattern 216b of the fuse pattern 220b is removed. In this instance, about half the thickness of the metal pattern 216b is removed. Accordingly, as illustrated in FIG. 1, formation of the fuse 220c having a stacked structure including the conductive pattern 212c formed of a material causing a thermal explosion when it absorbs a laser beam and the metal patterns 214c and 216c is completed.

In using the fuse 220c formed in accordance with the fabrication method described above, if a laser beam is radiated onto the fuse 220c during a repairing process, a temperature of the conductive pattern 212c formed under the fuse 220c and made of polysilicon rises. When the temperature of the conductive pattern 212c rises to a predetermined degree, the conductive pattern 212c is turned into a gas state and a thermal explosion occurs. That is, the metal patterns 214c and 216c formed over the conductive pattern 212c are blown off. Thus, a metal pattern residue does not remain after the repairing process since the metal patterns 214c and the 216c are converted into a gas state via a liquid state.

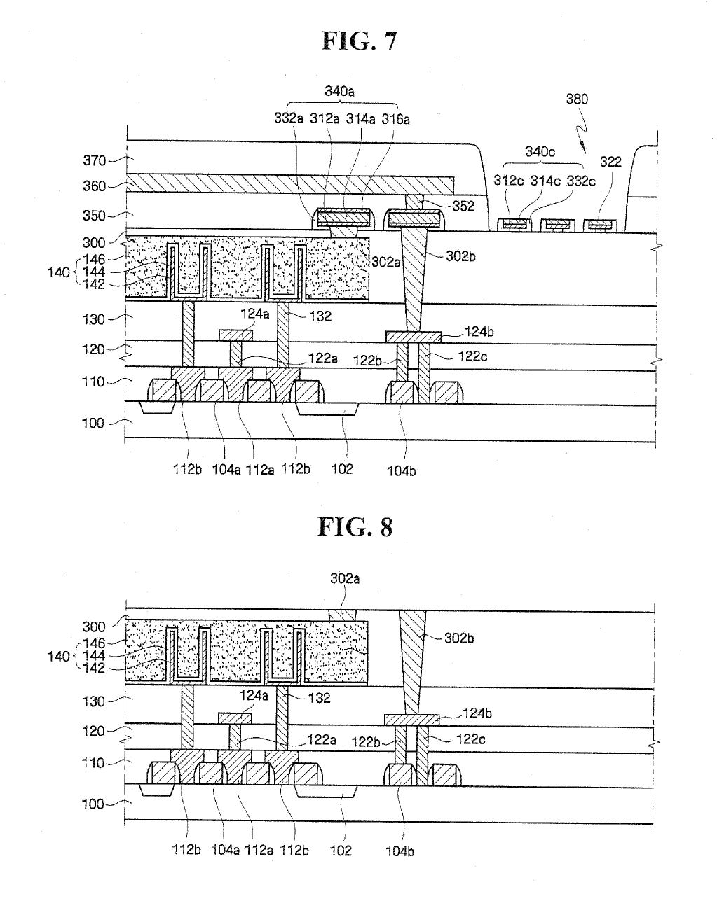

Next, a semiconductor memory device according to some other embodiments of the invention and a method for fabricating the same will be described in detail with reference to FIGS. 7 through 13. In the following description and drawings, the same reference numerals are used to designate the sane or similar components, and so repetition of the description on the same or similar components will be omitted.

FIG. 7 illustrates a semiconductor memory device according to some other embodiments of the invention.

Referring to FIG. 7, gate electrodes 104a and 104b, a bit line 124a, a capacitor 140 and contacts 112a, 112b, 122a, 122b and 132 disposed on a substrate 100 are structured the same as in the semiconductor memory device of FIG. 1.

In distinction from FIG. 1, however, a fourth interlayer insulating layer 300 is disposed on the capacitor 140, and a first wiring 340a and a fuse 340c are formed on the fourth interlayer insulating layer 300. The fuse 340c includes a metal pattern 314c of which a part of a lower surface is exposed and a spacer 332c formed to cover the exposed lower surface and sidewalls of the metal pattern 314c. In greater detail, a barrier metal pattern 312c for preventing the metal pattern 314c from being damaged is formed under the metal pattern 314c. Thus, both sides of the lower surface of the barrier metal pattern 312c are substantially exposed, and spacers 332c are provided on the exposed lower surface of the barrier metal pattern 312c and on side walls of the barrier metal pattern 312c and the metal pattern 314c. In addition, an interlayer insulating layer 322 is disposed at the center of the lower surface of the barrier metal pattern 312c. That is, a projecting pattern is formed on the fourth interlayer insulating layer 300 in the fuse region.

Alternatively, the fuse 340c may have the metal pattern 314c such that a part of a lower surface of the metal pattern 314c is exposed at both sides, and the barrier metal pattern 312c may be disposed under a center portion of the metal pattern 314c. The spacer 332c may be formed to cover the exposed lower surface and sidewalls of the metal pattern 314c.

The spacer 332c of the fuse 340c is formed of a material causing a thermal explosion when it absorbs a laser beam. Thus, when a laser beam is radiated onto the fuse 340c during a repairing process, the temperature of the spacer 332c rises. Then, the spacer 332 in a solid state is turned into a gas state. Meanwhile, a thermal explosion occurs. Accordingly, the barrier metal pattern 312c and the metal pattern 314c formed on or in the spacer 332 are blown off, leaving no residues.

The barrier metal pattern 312c of the fuse 340c may be composed of a refractory metal, a refractory metal compound, and/or a composite layer of a refractory metal and a refractory metal compound such as titanium (Ti), tantalum (Ta), titanium nitride (TiN) or tantalum nitride (TaN). The metal pattern 314c may be composed of aluminum (Al), tungsten (W), copper (Cu), and the like, and the spacer 332c may be composed of polysilicon.

In the cell array region, the first wiring 340a is formed on the fourth interlayer insulating layer 300, and the first wiring 340a includes the structure of the fuse 340c. The first wiring 340a includes a metal pattern 314a, of which a part of the lower surface is exposed, and a spacer 332a structured to cover the exposed part and side walls of the metal pattern 341a. In greater detail, the first wiring 340a has a stacked structure including a barrier metal layer 312a, a metal pattern 314a, and a capping pattern 316a, and a lower surface of the barrier metal layer 312a is partially exposed. The spacer 332a is provided on the lower surface of the exposed barrier metal layer 312a and the sidewalls of the stacked structure of the barrier metal layer 312a, the metal pattern 314a, and the capping pattern 316a.

On the other hand, wiring contacts 302a and 302b are disposed under the unexposed metal barrier patterns 312a. That is, an upper part of each of the wiring contacts 302a and 302b is surrounded by the spacer 332a, and a lower part of each of the wiring contacts 302a are disposed in the fourth interlayer insulating layer 300. A fifth interlayer insulating layer 350 is disposed on the first wiring 340 and a second wiring 360 is disposed on the fifth interlayer insulating layer 350 in the cell array region. The second wiring 360 and the first wiring 340 are electrically connected by the contact. A protective layer 370 is formed to cover the second wiring 360. The fifth interlayer insulating layer 350 and the protective layer 370 have an opening 380 to expose the fuse 340c in the fuse region.

A method for fabricating the semiconductor memory device of FIG. 7 will be described in more detail with reference to FIGS. 8 through 13. FIGS. 8 through 13 are sectional diagrams illustrating exemplary processes in the method for fabricating the semiconductor memory device shown of FIG. 7.

Referring to FIG. 8, the processes for fabricating gate electrodes 104a and 104b, a bit line 124a, contacts 112a, 112b, 122a, 122b, 122c and 132, and a capacitor 140 are the same as those described with reference to FIGS. 2 through 6. Accordingly, an unnecessarily repetitive explanation is omitted. After forming the capacitor 140, an oxide material is deposited on a surface of the resultant structure and planarized to form a fourth interlayer insulating layer 300. Here, the fourth interlayer insulating layer 300 may be formed of a borosilicate glass (BSG) layer, a phosphosilicate glass (PSG) layer, a borophosphosilicate glass (BPSG) layer, an undoped silicate glass (USG) layer, a tetra-ethyl-ortho-silicate (TEOS) layer, an O₃-TEOS layer, a PE (Plasma Enhanced)-TEOS layer, and the like.

Next, photoresist patterns (not shown) for wiring contacts 302a and 302b are formed on the fourth interlayer insulating layer 300. Next, using the photoresist patterns (not shown) as an etch mask, the fourth interlayer insulating layer 300 and the third interlayer insulating layer 130 are partially etched to expose the upper electrode 146 of the capacitor 140 and an wiring 124 in the peripheral circuit region. Next, a conductive material is deposited on the entire surface and planarized until the fourth interlayer insulating layer 300 is exposed, thereby forming the for wiring contacts 302a and 302b. The conductive material filling the fourth interlayer insulating layer 300 may be formed of doped polysilicon or tungsten.

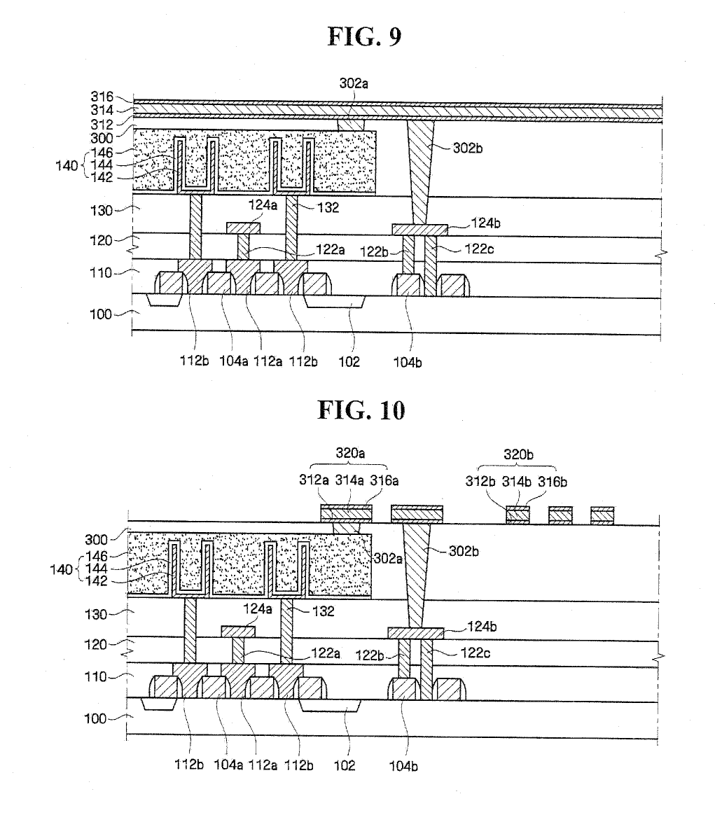

Referring to FIG. 9, a barrier metal layer 312, a metal layer 314, and a capping layer 316 are sequentially formed on the fourth interlayer insulating layer 300 having the wiring contacts 302a and 302b therein.

Here, the barrier metal layer 312 nay be composed of a refractory metal, a refractory metal compound, and/or a composite layer of a refractory metal and a refractory metal compound such as titanium (Ti), tantalum (Ta), titanium nitride (TiN), or tantalum nitride (TaN). The metal layer 314 may be composed of aluminum (Al), tungsten (W), copper (Cu), and the like. The capping layer 316 is disposed over the metal layer 314, prevents the metal layer 314 from being damaged, and may be made of the same material as the barrier metal layer 312.

Referring to FIG. 10, photoresist patterns (not shown) for forming the first wirings 340a and fuse patterns 340b are formed on the capping layer 316. Next, the capping layer 316, the metal layer 314, and the barrier metal layer 312 are sequentially partially etched to form the first wiring patterns 320a and the fuse patterns 320b. The first wirings 320a are connected to the wiring contacts 302a and 302b formed in the fourth interlayer insulating layer 300.

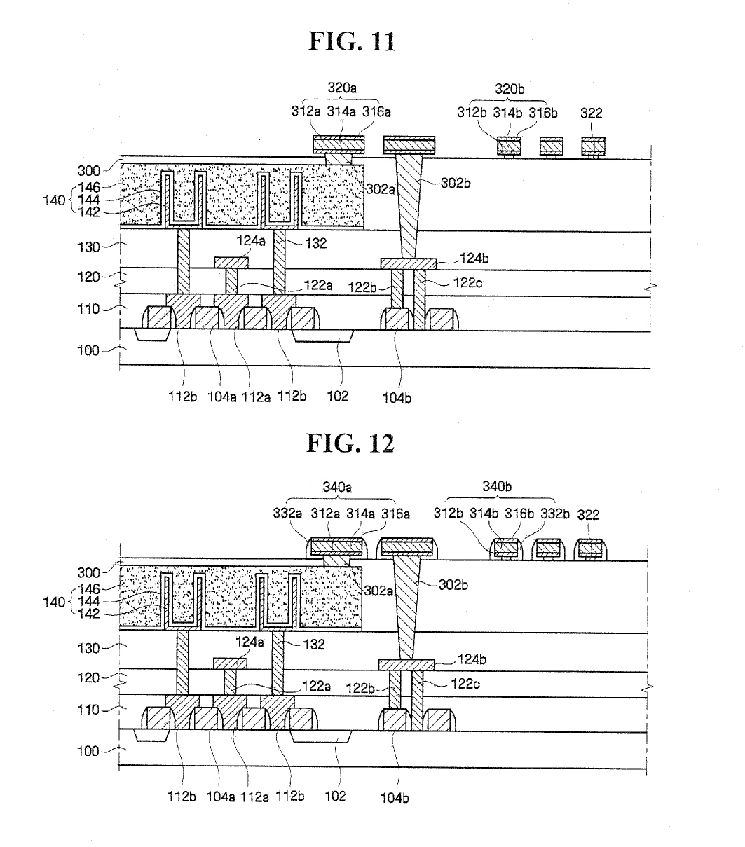

Referring to FIG. 11, the resultant structure shown in FIG. 10 is wet etched by an etchant solution used to wet etch the fourth interlayer insulating layer 300, in order to remove a predetermined thickness of the fourth interlayer insulating layer 300. In this instance, the wet etching is performed so that an undercut is caused to expose a lower part of the fuse patterns 320b. In other words, the metal barrier patterns 312b contained in the fuse pattern 320b is partially exposed. A part of the metal barrier patterns 312b disposed on the lower portion of the fuse pattern 320b forms an insulating layer pattern 322 to support the fuse patterns 320b. While the wet etching of the resultant structure of FIG. 10 occurs, a part of the lower surface of the first wiring 320a is exposed.

After a part of the bottom of each of the first wiring 320a and the fuse pattern 320b is exposed as described above, referring to FIG. 12, spacers 332a and 332b are formed on the exposed lower surfaces and sidewalls of the first wirings 320a and the fuse patterns 320b. The spacers 332a and 332b consist of a material that causes a thermal explosion when its absorbs the energy of a laser beam, such as polysilicon. Accordingly, referring to FIG. 12, the first wiring 340a and the fuse pattern 340b are formed to have spacers 332a and 332b on a portion of the lower surface and sidewalls thereof.

More specifically, a material that causes a thermal explosion when it absorbs the energy of a laser beam, that is, polysilicon, is deposited on the first wiring 320a and the fuse pattern 320b, each part of the bottom of which is exposed, and then anisotropically etched until the fourth interlayer insulating layer 300 is exposed. In this way, the exposed bottom portions are filled with polysilicon and the spacers 332a and 332b are formed on sidewalls of the lower surface.

While the fourth interlayer insulating layer 300 is wet etched to form the first wiring 340a and the fuse pattern 340b having spacers 332a and 332b in the illustrated embodiment, the invention is not limited thereto. For example, in a fuse having a stacked structure a barrier metal pattern and a metal pattern, side portions may be partially removed and a bottom portion may be partially exposed, followed by forming spacers on the lower portion and the side portions.

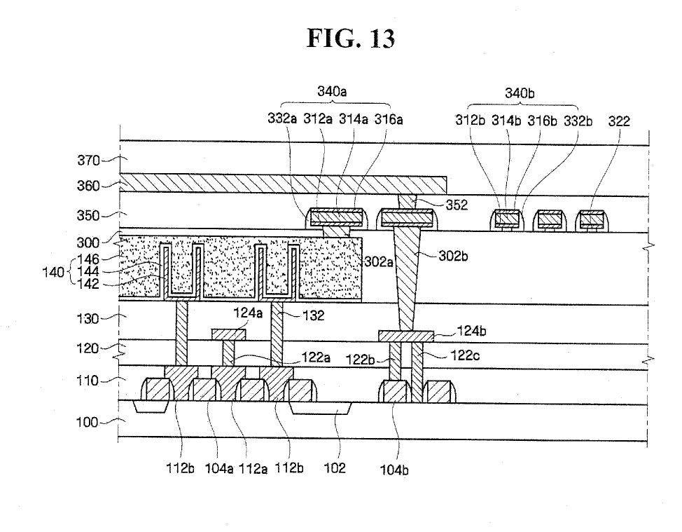

Referring to FIG. 13, the fifth interlayer insulating layer 350 is formed to cover the first wiring 340a and the fuse pattern 340b, having the spacers 332a and 332b formed on part of the lower surface and the sidewalls thereof. Next, a contact 352 for connecting wirings is formed in the fifth interlayer insulating layer 350 and then a metal layer for a second wiring 360 is formed on the fifth interlayer insulating layer 350 and patterned to form the second wiring 360. Here, a barrier metal layer may be formed to cover the second wiring 360 and a capping layer may further be formed thereon. Thereafter, a protective layer 370 is deposited on the entire surface of the resulting structure.

Next, photoresist patterns (not shown) for exposing the fuse pattern 340b are formed on the protective layer 370. Then, an opening (380 of FIG. 7) is formed to expose the upper surfaces of the fourth interlayer insulating layer 300 and the fuse pattern 340b by sequentially and partially etching the protective layer 370 and the fifth interlayer insulating layer 350. Next, the fuse pattern 340b is partially dry etched. That is to say, a part of the spacer 332b, the capping layer 316b and the metal layer 314b of the fuse pattern 340b is removed. In this instance, about half the thickness of the metal layer 314b is preferably removed. Finally, as illustrated in FIG. 7, the fuse 340c, which includes the barrier metal pattern 312c of which a part of a lower surface is exposed, the metal pattern 314c disposed on the barrier metal pattern, and spacers 332 formed on the exposed lower surface of the barrier metal pattern 312c and on sidewalls of the barrier metal pattern 312c and the metal pattern 314c, is completely formed.

Thus, if a laser beam is radiated onto the fuse 340c during a repairing process, the temperature of the polysilicon spacers 332 rises. The solid-state spacers 332 transition to a gaseous state when the temperature of the spacers reaches a predetermined value. That is, a thermal explosion occurs, Accordingly, the barrier metal pattern 312c and the metal pattern 314c formed on or in the spacers 332 are blown off, leaving no residues behind.

While the above-described embodiments have been described that fuses are formed on the same layer as the first wiring, the invention is not limited thereto. For example, when an upper electrode of a capacitor is formed of a metallic material, a fuse may be formed on the same layer as the upper electrode. Alternatively, a fuse may be formed on the same layer as other wirings overlying the first wiring.

As described above, in a semiconductor memory device according to some embodiments of the invention, since an underlying layer of a fuse is formed of a conductive material causing a thermal explosion when it absorbs a laser beam, the conductive pattern underlying the fuse is thermally exploded when a laser beam is radiated to the fuse during the repairing process of the semiconductor memory device. Accordingly, residues which would otherwise be generated from the metal pattern formed on the conductive pattern are blown off when the conductive pattern is thermally exploded.

The invention may be practiced in many ways. What follows are exemplary, non-limiting descriptions of some embodiments of the invention.

According to some embodiments, a semiconductor memory device includes an insulation layer formed on a substrate at a location where a fuse is to be formed and a fuse. The fuse has a stacked structure including a conductive pattern disposed on the insulation layer and made of a material which causes a thermal explosion when it absorbs the energy of a laser beam and a metal pattern disposed on the conductive pattern.

According some embodiments, a method of fabricating a semiconductor memory device includes depositing a conductive layer formed of a material which causes a thermal explosion when it absorbs a laser beam on an insulation layer in a fuse region, depositing a metal layer on the conductive layer, and forming a fuse by etching the metal and the conductive layer until the insulation layer is exposed, the fuse having a stacked structure including a conductive pattern and a metal pattern.

According to some embodiments, a semiconductor memory device includes an insulation layer disposed on a substrate in a fuse region, and a fuse including a metal pattern formed on the insulation layer, wherein part of a lower surface of the metal pattern is exposed and a spacer formed of a material which thermally explodes when it absorbs energy of a laser beam is formed on the exposed lower surface and sidewalls of the metal pattern.

According to some embodiments, a method for fabricating a semiconductor memory device includes forming a metal pattern on an insulation layer in a fuse region, wherein at least part of a lower surface of the metal pattern is exposed, and completing formation of a fuse by forming a spacer on the exposed lower surface and sidewalls of the metal pattern using a material which thermally explodes when it absorbs energy of a laser beam.

Consequently, after the repairing process of the semiconductor memory device, leakage currents caused by residues from the metal pattern may be prevented.

Those skilled in the art will appreciate that many variations and modifications can be made to the preferred embodiments without substantially departing from the inventive principle or principles that are exhibited by disclosed embodiments. Therefore, the disclosed preferred embodiments of the invention are used in a generic and descriptive sense only and not for purposes of limitation.

1. A semiconductor memory device comprising:
an insulation layer disposed in a fuse region of a substrate; and
a fuse including a conductive pattern disposed on the insulation layer and a metal pattern disposed in physical contact with the conductive pattern, the conductive pattern composed of a material that thermally explodes when it absorbs a laser beam.

2. The semiconductor memory device of claim 1, wherein the insulation layer is further disposed in a cell array region of the substrate.

3. The semiconductor memory device of claim 2, wherein a wiring having the same structure as the fuse is formed in the cell array region.

4. The semiconductor memory device of claim 1, wherein the conductive pattern comprises a polysilicon pattern.

5. The semiconductor memory device of claim 1, further comprising a barrier metal pattern between the conductive pattern and the metal pattern.

6. A method for fabricating a semiconductor memory device, the method comprising:
depositing an electrically conductive layer on an insulation layer in a fuse region of a substrate, the electrically conductive layer formed or a material that transitions from a solid to a gaseous state after absorbing sufficient energy from a laser;
depositing a metal layer on the electrically conductive layer; and
forming a fuse by etching the metal layer and the electrically conductive layer until the insulation layer is exposed, the fuse having a stacked structure that includes an electrically conductive pattern and a metal pattern.

7. The method of claim 6, wherein the insulation layer is disposed in a cell array region of the substrate.

8. The method of claim 7, Wherein a wiring having the same structure as the fuse is formed in the cell array region of the substrate.

9. The method of claim 6, wherein the electrically conductive pattern comprises a polysilicon pattern.

10. The method of claim 6, wherein the metal layer is composed of one selected from the group consisting of aluminum (Al), tungsten (W), and copper (Cu).

11. The method of claim 6, further comprising, after depositing the electrically conductive layer, depositing a barrier metal layer.

12. The method of claim 11, wherein depositing the barrier metal layer comprises depositing at least one layer selected from the group consisting of a titanium (Ti) layer, a tantalum (Ta) layer, a titanium nitride (TiN) layer, and a tantalum nitride (TaN) layer.

13. A semiconductor memory device comprising:
an insulation layer disposed in a fuse region of a substrate;
a fuse disposed on the insulation layer, the fuse including a metal pattern; and
a spacer disposed in physical contact with a sidewall of the metal pattern, the spacer composed of a material that thermally explodes when a temperature of the material reaches a specific value.

14. The semiconductor memory device of claim 13, wherein the insulation layer is disposed in a cell array region of the substrate.

15. The semiconductor memory device of claim 14, wherein a wiring having the same structure as the fuse is formed in the cell array region.

16. The semiconductor memory device of claim 13, wherein the spacer is composed of polysilicon.

17. The semiconductor memory device of claim 13, further comprising a barrier metal pattern disposed between the insulation layer and the metal pattern, the spacer disposed in physical contact with a lower surface of the barrier metal pattern.

18. The semiconductor memory device of claim 17, wherein a portion of the lower surface of the barrier metal pattern is exposed.

19. The semiconductor memory device of claim 18, wherein the spacer is disposed in physical contact with a sidewall of the barrier metal pattern.

20. A method of fabricating a fuse in a semiconductor memory device, the method comprising:
forming a metal pattern on an insulation layer in a fuse region of the semiconductor memory device; and
forming a spacer in physical contact with a lower surface and a sidewall of the metal pattern, the spacer composed of a material that thermally explodes when it absorbs a sufficient amount of energy from a laser beam.

21. The method of claim 20, wherein the insulation layer is disposed in a cell array region.

22. The method of claim 21, wherein a wiring having the same structure as the fuse is formed in the cell array region.

23. The method of claim 20, wherein forming the metal pattern comprises:
depositing a metal layer on the insulation layer;
patterning the metal layer to form the metal pattern; and
wet etching the insulation layer and the metal pattern to expose the lower surface of the metal pattern.

24. The method of claim 23, wherein depositing the metal layer comprises depositing one selected from the group consisting of an aluminum (Al) layer, a tungsten (W) layer, and a copper (Cu) layer.

25. The method of claim 23, wherein forming the spacer comprises forming the spacer of polysilicon.

26. The method of claim 23, further comprising depositing a barrier metal layer between the insulation layer and the metal layer.

27. The method of claim 26, wherein the barrier metal layer and the metal layer are simultaneously patterned.

28. The method of claim 27, wherein the lower surface of the barrier metal is exposed.

29. The method of claim 26, wherein depositing the barrier metal layer comprises depositing at least one layer made of a material selected from the group consisting of titanium (Ti), tantalum (Ga), titanium nitride (TiN), and tantalum nitride (TaN).
